(19) United States
(12) Patent Application Publication
(10) Pub. No.: US 2013/0059412 A1
(43) Pub. Date: Mar. 7, 2013

(54) IN-SITU POLYMERIZATION IN BULK HETEROJUNCTION ORGANIC DEVICES

(71) Applicants: Harald W. Ade, Cary, NC (US); Jaewook Seok, Raelgih, NC (US)

(72) Inventors: Harald W. Ade, Cary, NC (US); Jaewook Seok, Raelgih, NC (US)

(73) Assignee: NORTH CAROLINA STATE UNIVERSITY, Raleigh, NC (US)

(21) Appl. No.: 13/696,073

(22) PCT Filed: May 4, 2011
(86) PCT No.: PCT/US11/35257

§ 371 Date: Nov. 19, 2012

Related U.S. Application Data
(60) Provisional application No. 61/331,358, filed on May 4, 2010.

(51) Int. Cl. H01B 1/12; H01L 51/48

(52) U.S. Cl. 438/82; 252/500; 252/510; 257/E51.026

(57) ABSTRACT

Fabrication of bulk heterojunction organic devices are disclosed that utilize in-situ polymerization of an active component of the device or an in-situ polymerization of an additive that controls the device morphology. According to an aspect, a method for the synthesis of a BHJ photovoltaic film may comprise preparing a homogeneous solution comprising 2,5-dibromothiophene and/or 2,5-diiodothiophene, P3HT and PCBM. The method may also comprise preparing a thin film of the homogeneous solution on the solid surface of a material or an assembly capable of acting as an anode. Oxygen may be excluded from the environment where the thin film will be exposed to photopolymerization by placing the thin film and anode assembly in an inert-gas environment. The method also comprises exposing the liquid film to UV light for a sufficient duration of time and at a sufficient temperature to cause photopolymerization to occur.

### CROSS REFERENCE TO RELATED APPLICATIONS

This application is a 371 application of PCT International Patent Application PCT/US2011/035257, filed on May 4, 2011 and which claims priority to U.S. Provisional Patent Application No. 61/331,358, filed May 4, 2010, which are all hereby incorporated herein by reference in their entireties.

### FEDERALLY SPONSORED RESEARCH OR DEVELOPMENT

The technology disclosed herein was made with government support under grant number DE-FG02-98ER45737 awarded by the Department of Energy, Office of Science, Office of Basic Energy Science, and Division of Materials Science and Engineering. The United States government may have certain rights in the technology.

### TECHNICAL FIELD

The present disclosure relates to bulk heterojunction organic devices. Particularly, the present disclosure relates to the in-situ polymerization of at least one component in bulk heterojunction organic devices.

### BACKGROUND

Photovoltaics are well known and promising technologies to solve the future energy needs and to, maybe more importantly, reduce emission of CO₂, a major green house gas. Energy from the sun is sufficient to cover the yearly total requirement for the world from several tens of minutes of sunlight energy. Although only a small amount of energy can reach the surface of the earth, photovoltaics could be regarded, along with biofuels, as long-term, low CO₂ emission, renewable energy sources. The potential of photovoltaics is even larger than that of biofuels, as arid areas can be successfully utilized for energy creation. Over the past several decades, there have been marked improvements in photovoltaic technology, achieving efficiencies as high as 40% in advanced inorganic photovoltaic devices and 15-20% in commercially available devices.

The first solid state organic photovoltaics showing reasonable power conversion efficiency were developed using phthalocyanine and perylene derivatives. Several other materials classes such as Buckminster fullerene (C61), carbon nanotubes, conducting polymers, and their derivatives have been evaluated. Among them, the most promising materials are polythiophene and its soluble derivatives such as in poly(3-hexylthiophene) (P3HT). These materials have superior thermal and environmental stability to any other semiconducting polymers, for example, poly(p-phenylene vinylene) (PPV).

A major improvement in efficiency occurred with the development of bulk heterojunction (BHJ) devices. Exemplary schematic diagrams of BHJ devices are illustrated in FIGS. 1(a), 1(b), 1(c), 1(d) and 2. Particularly, FIG. 1A is a schematic diagram of an organic photovoltaic, particularly a thermodynamically-driven BHJ formed by phase segregation during thermal annealing. FIG. 1B is a schematic diagram of an organic photovoltaic, particularly a BHJ with a large donor-acceptor interface area and continuous carrier-conducting pathways to the opposing electrodes formed by controlled small-molecule growth. FIG. 1C is a schematic diagram of an organic photovoltaic, particularly having a planar heterojunction. FIG. 1D is a schematic diagram of a controlled BHJ photovoltaic device structure grown on top of indium tin oxide (ITO)-coated glass. FIG. 2 is a schematic illustration of BHJ photovoltaic device structures based on P3HT.

At current growth rates, it would take decades for photovoltaics to emerge as a major energy source contributor. The growth is impeded mostly by the high fabrication and maintenance costs of the types of inorganic devices currently employed. Organic photovoltaics have become an attractive alternative to inorganic devices. A major advantages of organic, e.g., polymeric, photovoltaics are low production costs and easy fabrication using conventional printing or coating technologies. However, presently, organic devices are not as efficient as their inorganic counterparts, and their durability is yet to be proven. None-the-less it is not the efficiency of a solar cell that is most important for mass production, but the lifetime cost per watt of energy produced. Less efficient cells simply require more land/area to be covered, which will not be the limiting factor if devices meet a minimum efficiency of about 5-10%. Consumers will see widespread use of solar energy only if its costs can be significantly reduced (by a factor of 10), and if there will be limited environmental impact by component manufacturing and installation.

One of the main differences in the function of inorganic and organic photovoltaics is the binding energy of the exciton (a bound electron—hole pair) that is created by the absorption of a photon. Strongly bound excitons (about 0.2-0.3 eV) result in organic semiconductors, whereas quasi-free charge carriers are created directly in inorganic semiconductors.

To harvest much of the energy of the absorbed photon in organic materials, the charges of the excitons have to be successfully dissociated. This can be achieved on the fs timescale at the interface of electron—donor and—acceptor materials with appropriate valance and conduction band energies. Generally, electron donors and electron acceptors have a small ionization potential and a large electron affinity, respectively, creating favorable energetic to overcome the exciton binding energy. The donor/acceptor interface has to be located within the exciton's diffusion length (about 10 nm) of the site of the photo absorption, or else the exciton decays and the energy of the absorbed photon is lost. Furthermore, there should be a continuous path for the dissociated charges towards both electrodes, which is trivially achieved in a thin planar heterojunction. However, for efficient absorption of light, the thickness of the active organic layer should be about 100-150 nm. This length scale is not matched to the exciton diffusion length and is about an order of magnitude larger creating a major engineering challenge.

The ideal device needs lateral structures on the order of 10 nm, within a film at least 10 times as thick. In addition, the lateral structures need to be sufficiently connected, preferably via a completely interpenetrating network or nano-posts with good and matched transport properties. This device design and engineering challenge has been most successfully addressed to date with the creation of bulk heterojunction (BHJ) structures. In some BHJ structures, donor and acceptor materials are co-dissolved in a common solvent and spun-cast or printed into a thin film. Efficiencies of 5-6% have been achieved in poly(3-hexylthiophene) P3HT: [6,6]-phenyl-C₆₁Fullerene-butyric acid methyl ester (PCBM) systems. Simple solvent casting process for the formation of thin BHJ films is a great strength, but has also major disadvantages. Significant synthesis efforts have been and are spent to improve the solubility of relevant compounds to increase the range of solvents and materials that can be used. Still, the currently-used organic solvents for P3HT and PCBM bulk heterojunction system, such as dichlorobenzene and cholorobenzene, are very toxic. Furthermore, the morphology development is driven by the solvent evaporation and secondary thermal annealing. While this has lead to relatively good morphological control in some systems, notably in P3HT:PCBM, it has met with more limited success in all polymer based systems such as poly(9,9′-dioctylfluorene-co-bis(N,N′-(4,butylphenyl))bis(N,N′-phenyl-1,4-phenylene)diamine) (PFB) with poly(9,9′-dioctylfluorene-co-benzothiadiazole) (F8BT). Even for materials that yield highly controlled, small morphologies in the laboratory, controlling the evaporation rates during printing or spin-coating process during commercial fabrication of large devices may be difficult and the required repeatability may not be achievable for many systems.

### SUMMARY

In view of the foregoing, there is a need to improve the technology for the creation of BHJ devices. In particular, technology is needed for producing BHJ devices in order to increase the engineering options for eventual device fabrication and decrease any environmental impact of manufacturing. Technology and techniques for in-situ polymerization of bulk heterojunction (SF-BHJ) organic devices, such as photovoltaics, are disclosed herein. In addition, the techniques disclosed herein may be used to control the morphology, the degree of crystallinity and the crystallite orientation of BHJ devices.

A first aspect of the technology disclosed herein is a homogeneous composition for in-situ polymerization to form bulk heterojunction (SF-BHJ) organic devices including a monomer, or functional oligomer, capable of polymerization upon short wave length photoirradiation, an electron donor material, and an electron acceptor material.

In an embodiment of one aspect, the monomer, or functional oligomer, is capable of polymerizing to form a polythiophene having an average molecular weight greater than 500 g/mol upon short wave length photoirradiating, such as, for example, irradiating with ultraviolet light. A suitable monomer is a 2,5-dihalothiophene, such as 2,5-dibromothiophene or 2,5-diiodothiophene. In another embodiment, the electron donor material is at least one poly(3-alkyl-2,5-thiophene) wherein the alkyl group has one to twelve carbon atoms. In yet another embodiment, the acceptor donor material is one or more derivatives of a fullerene, such as [6,6]phenyl-C₆₁fullerene-butyric acid methyl ester (PCBM). In yet another embodiment, the electron donor or the electron acceptor materials is eliminated from the initial mixture and instead synthesized in-situ. In a further embodiment the acceptor donor material is carbon nanotubes or derivatives of carbon nanotubes.

A second aspect of the present disclosure is a method for, in-situ synthesis of bulk heterojunction (BHJ) organic devices, such as a BHJ photovoltaic film, includes spin casting the homogeneous composition of the first aspect onto a thin film on a solid substrate capable of acting as an anode, and photoirradiating the thin film, preferably with ultraviolet light in an atmosphere substantially devoid of oxygen for a sufficient duration of time and at a sufficient temperature to cause photopolymerization to occur within the thin film.

### BRIEF DESCRIPTION OF THE DRAWINGS

The foregoing summary, as well as the following detailed description of preferred embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIGS. 1(a), 1(b), 1(c), 1(d) are schematic diagrams of BHJ devices;

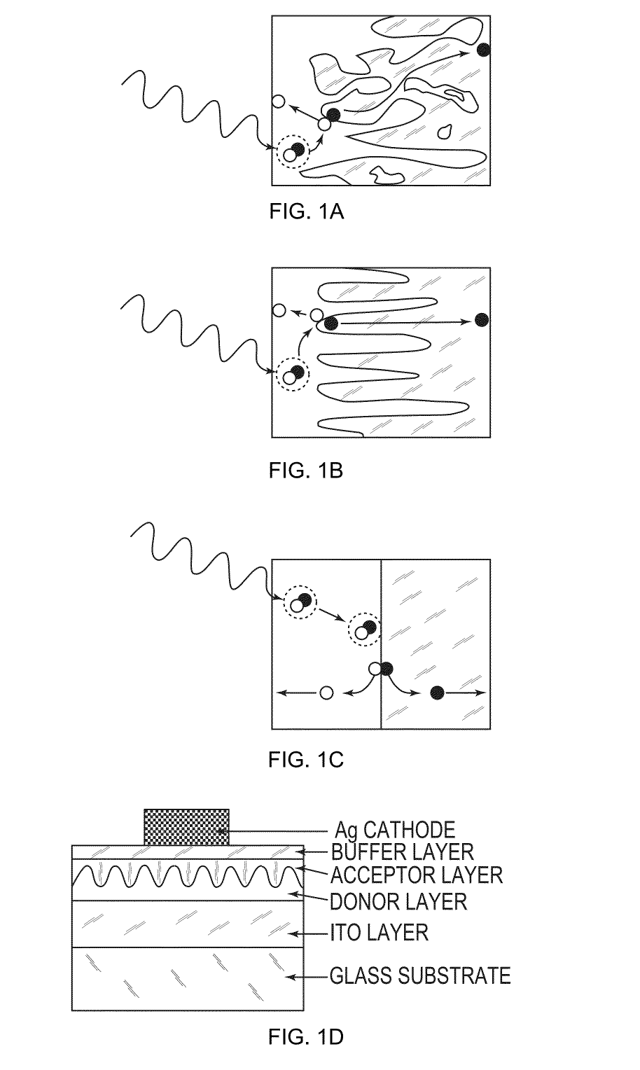

FIG. 2 illustrates schematic drawings of BHJ photovoltaic device structures based on P3HT and PCBM, the chemical structures, and energy band diagram of the materials used;

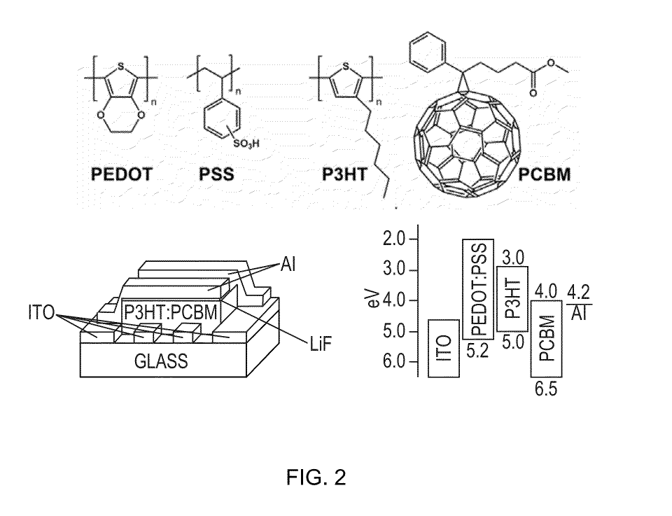

FIG. 3 illustrates the chemical reactions utilized for the in-situ process.

FIGS. 4(a) and 4(b) depict experimental results, namely illustrating the current-voltage (IV) characterization of an in-situ polymerization of BHJ device;

FIG. 5 depicts a graph of experimental results of an IV curve of P3HT:PCBM BHJ control devices having 2.5% power conversion efficiency;

FIGS. 6(a) and 6(b) are charts showing iodine doping effect on a polythiophene/porphyrin based polymer solar cell;

FIGS. 7 (a) and 7(b) are experimental results, namely illustrating the IV characterization of a BHJ device based on DBT vapor exposure and in-situ polymerization;

FIG. 8 illustrates an example of the P3HT crystalline orientation and GIWAXS data on P3HT:PCBM model films according to embodiments of the present disclosure;

FIG. 9 illustrates an exemplary process of in situ fabrication of in situ polymerized bulk heterojunction organic devices according to embodiments of the present technology; and

FIG. 10 illustrates an exemplary process of device fabrication according to embodiments of the present disclosure.

### DETAILED DESCRIPTION

While the disclosure of the technology herein is presented with sufficient details to enable one skilled in this art to practice the invention, it is not intended to limit the scope of the disclosed technology. The inventors contemplate that future technologies may facilitate additional embodiments of the presently disclosed subject matter as claimed herein. Moreover, although the term “step” may be used herein to connote different aspects of methods employed, the term should not be interpreted as implying any particular order among or between various steps herein disclosed unless and except when the order of individual steps is explicitly described.

Terms frequently used herein:

“BHJ”—bulk heterojunction;

“2,5-BHT”—2,5-dihalothiophene;

“2,5-DBT”dibromothiophene;

“2,5-DIT”—2,5-diiodothiophene;

“CNT”—carbon nanotube (CNT);

“ITO”—indium tin oxide;

“OTFTs”—organic thin film transistors;

“PCB—printed circuit board;

“P3HT”—poly(3-alkyl-2,5-thiophene);

“PCBM”—[6,6]-phenyl-C₆₁Fullerene-butyric acid methyl ester;

“polymer”—including “functionalized oligomer.” is a molecule or small group of molecules that under chemical or physical catalyzation is capable of forming large molecules, i.e. polymers;

“polymerized BHJ device”—BHJ device produced by the technology of the disclosure; and

“SF-BHJ”—bulk heterojunction that is substantially solvent free.

The disclosed technology provides improved BHJ devices and techniques for the creation thereof. Further, the technology achieves the goals, among others, of: developing and delineating the underlying fundamental science of in-situ polymerized bulk-heterojunction (BHJ) photovoltaics; exploiting polymerization-driven phase separation as a means to control morphology in BHJ devices: exploiting affinity of the monomer to the polymer backbone to drive crystallinity and crystal orientation in BHJ devices; using self-doping with iodine or another halide that occurs during the polymerization process of some monomers to improve device efficiency; and polymerizing monomers that penetrated aligned carbon nanotube (CNT) mats in-situ to create near ideal morphologies.

Techniques in accordance with the presently disclosed technology may be used to replace completely or partially conventional solvent based processes in organic solar cell, organic light emitting diodes (OLEDs), and organic thin film transistors (OTFTs).

According to one or more embodiments of the present disclosure, a method for in-situ synthesis of a BHJ photovoltaic film may include preparing a homogeneous solution including 2,5-dibromothiophene and/or 2,5-diiodothiophene, P3HT, and PCBM. The method may also include preparing a thin film of the homogeneous solution on the solid surface of a material or an assembly capable of acting as an anode. Oxygen may be excluded from the environment where the thin film will be exposed to photopolymerization by placing the thin film and anode assembly in an inert-gas environment. The method also includes exposing the film to UV light for a sufficient duration of time and at a sufficient temperature to cause photopolymerization to occur.

According to one or more embodiments of the present disclosure, another method for in-situ polymerization in bulk heterojunction photovoltaic film may include exposing a prepared film to the vapor 2,5-dibromothiophene and/or 2,5-diiodothiophene. Adsorbed 2,5-dibromothiophene and/or 2,5-diiodothiophene is subsequently polymerized.

In lieu of the conventional organic solvent used in the production of BHJ devices of the art, in the present disclosure a polymerizable monomer, such as a 2,5-dihalothiophene, may serve the function of a solvent. Although similar in overall action, the monomer has a high affinity for the backbone of organic seminconductors, whereas conventional solvents have a high affinity to the sidechains of organic seminconductors.

A composition according to embodiments of the present disclosure may include an organic polymer. The polymer may be synthesized by a process including the step of photo-irradiation of a liquid sample using short-wavelength ultraviolet light. The liquid may include 2,5-dibromothiophene or 2,5-diiodothiophene. The composition including the organic polymer may be a solid at 25° C.

According to one or more embodiments of the present disclosure, a thin photovoltaic film may include at least three components: a first component including a polythiophene in which the polythiophene has an average molecular weight greater than 500 g/mol, a second component including an electron donor material in which the electron donor material including one or more poly(3-(C₁₋₁₂)alkylthiophene); and a third component including an electron acceptor material in which the electron acceptor material includes one or more derivatives of a fullerene.

According to one or more embodiments of the present disclosure, another method for in-situ polymerization in bulk heterojunction photovoltaic film may include exposing a prepared film to the vapor 2,5-dibromothiophene and/or 2,5-diiodothiophene. Adsorbed 2,5-dibromothiophene and/or 2,5-diiodothiophene may be subsequently polymerized.

The present disclosure eliminates the need for solvent by creating thin films of a suitable two component, homogeneous composition in a monomeric, polymer precursor, and then irradiating those films with short wave length light in-situ to initiate polymerization. As the molecular weight of the polymer increases, the two component system phase-separate to create a desired BHJ morphology. Control over the developing morphology may be achieved by controlling the temperature and by admixing a variable fraction of high molecular weight, active materials to modify the viscosity of the phase separating material.

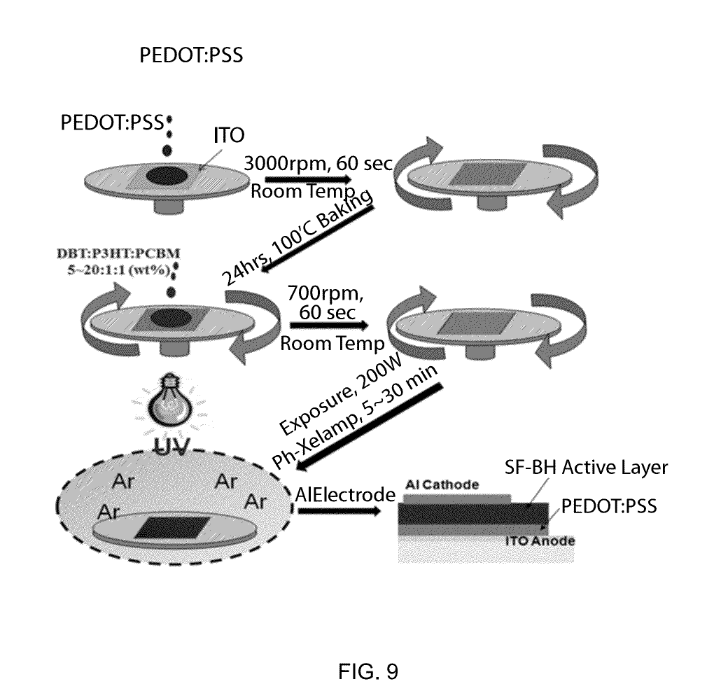

Achieving control over the required nano-morphology, crystallinity and crystal orientation is both crucial and difficult. BHJ photovoltaics taught in the art are fabricated by spin-coating or conventional printing from a homogeneous solution prepared from a co-solvent such as a substituted aromatic hydrocarbon, e.g., chlorobenzene, dichlorobenzene, and toluene. The desired nano-sized domains of an interpenetrating charge transport network are inherently unstable at elevated temperatures or solvent vapor exposure and initial starting conditions prior to thermal or solvent annealing presently used may not be ideal. Certain organic solvents used for the P3HT:PCBM BHJ system, such as dichlorobenzene and chlorobenzene, have high boiling temperatures making the control over the evaporation rates during printing or spin-coating process difficult. Consequently, repeatable nanophase separation is difficult to achieve. Crystal orientation with their high mobility axis normal to the thin film is highly desirable. This orientation is referred to a “face-on”, with the aromatic groups parallel to the plane of the thin film (e.g., see FIG. 9 for the unfavorable “edge-on” orientation).

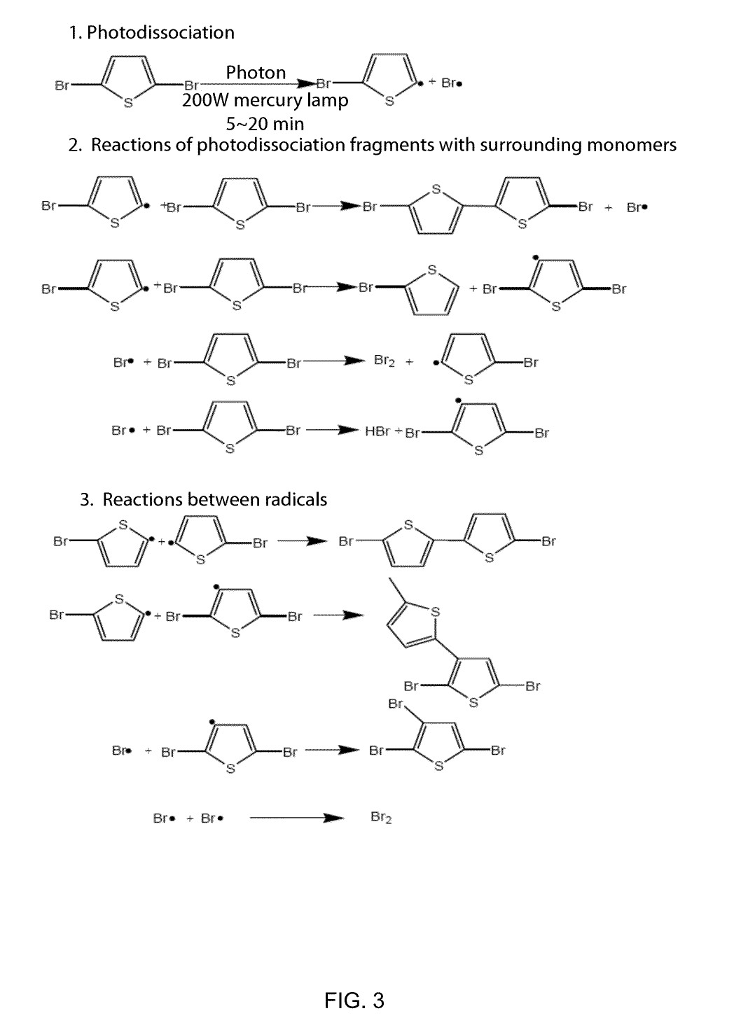

In accordance with one or more embodiments disclosed herein, the selective photodissociation of the C-halogen bond in 2,5-dihalothiophene (2,5-BHT), e.g. 2,5-dibromothiophene (DBT) and 2,5-diiodothiophene (DIT), produces a monomer radical with intact it ring structure. These radicals can then polymerize the 2,5-DHT to polythiophene providing a new synthesis pathway. The general photochemical reaction mechanism is shown in FIG. 3, which particularly illustrates a reaction mechanism of the photopolymerization of 2,5-DBT. In-situ polymerization can form thin films from unsubstituted polythiophene, whereas casting such a film from a solution is impossible due to the low solubility of polythiophene. Direct polymerization of polythiophene can thus broaden the range of materials used and increase the use of polythiophene in organic devices.

In accordance with one or more embodiments disclosed herein, it is discovered that 2,5-DHT, in particular 2,5-DBT, has high miscibility, not only with polythiophene and P3HT, but also with PCBM, and that homogeneous liquid phase mixture can be produced at room temperature, with little or no co-solvent or 2,5-DBT, both P3HT and PCBM are immiscible solid phase materials. In one embodiment of the method, a substantially conventional solvent free bulk heterojunction (SF-BHJ) polymeric photovoltaics have been developed through the use of an in-situ fabrication process

In accordance with one or more embodiments disclosed herein, SF-BHJ photovoltaic devices substantially free of solvent may be prepared by spin-coating a precursor thin film and subsequent UV induced polymerization. Several droplets of the prepared miscible mixture (2,5-DBT:P3HT:PCBM) are spin-coated on top of the pre-cleaned indium thin oxide (ITO) transparent electrode. UV light induced photopolymerization is carried out for 5-10 minutes at 80° C. in Ar₂ gas environmental to induce the nanoscale phase separation between the electron donor and acceptor materials due to the rapid decrease of the miscibility between them. This nanoscale phase separation between P3HT and PCBM are mainly driven not by the evaporation of 2,5-DBT (boiling point=211° C.), but by the photopolymerization of 2,5-DBT.

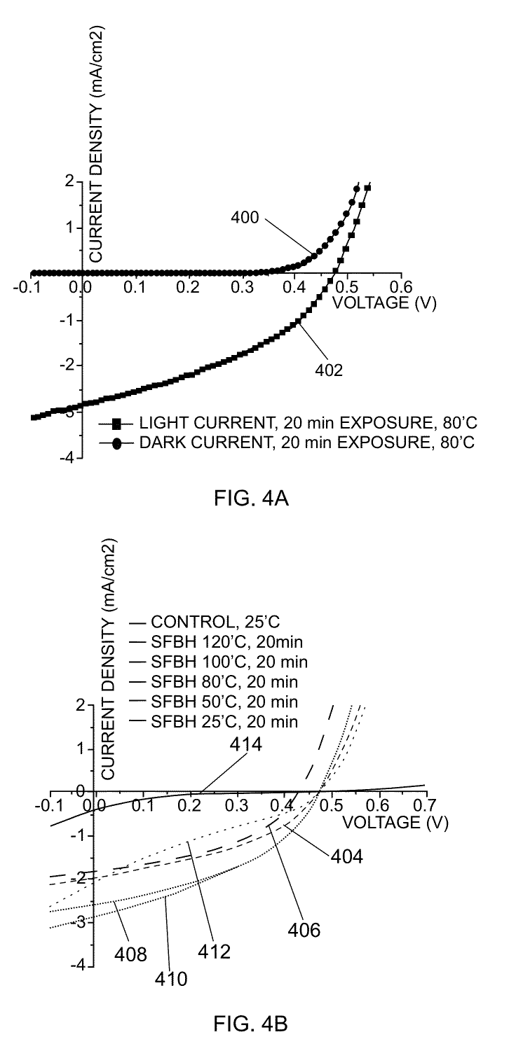

This photopolymerization reaction of 2,5-DBT may be carried out in a sealed inert environment, such as an Ar₂ gas environment, to minimize unwanted side effects during the UV photopolymerization. In the examples disclosed herein, the fabrication processes, short of AI cathode evaporation, were carried out inside an N₂-purged glove box. Experimental results such as IV characterization of the in-situ polymerized BHJ device are illustrated in FIGS. 4(a) and 4(b) showing UV irradiation and temperature dependence of in-situ polymerized BHJ devices. Particularly, FIG. 4(a) depicts dark/light current of in-situ polymerized BHJ devices. In FIG. 4(a), line 400 represents the dark current, and line 402 represents the light current. FIG. 4(b) depicts UV irradiation and temperature dependence of the in-situ polymerized BHJ efficiencies. In FIG. 4(b), line 404 represents the control at 25° C., line 406 represents 120° C., line 408 represents 100° C., line 410 represents 80° C., line 412 represents 50° C., and line 414 represents 25° C. In-situ polymerized BHJ devices disclosed herein and prepared according to methods and processes disclosed herein exhibited about 60% higher power conversion efficiency and about 12% higher fill factor than the control sample prepared by following the conventional co-solvent based processes.

In addition, the short circuit current (I_{SC}, mA/cm₂) of the in-situ polymerized BHJ device was about 27% higher than that of the control sample with little to no difference in the open circuit voltage (V_{OC}) of 0.45 V. It may be assumed that the formation of much smaller size of 3D network may result from polymerization-induced phase separation in comparison to solvent-induced phase separation, in turn leading to good performance. Furthermore, the degree of crystallization is increased and a more beneficial crystalline orientation might be achieved based on the stable and identical open circuit voltage (V_{OC}) values as a function of UV exposure, there was no severe degradation from UV irradiation in the experimental in-situ polymerized BHJ devices.

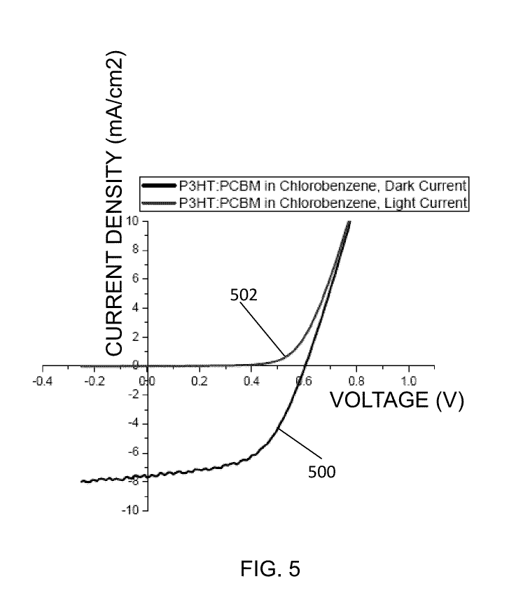

P3HT:PCBM BHJ control devices with power conversion efficiencies of 2.5% have been achieved. For example, FIG. 5 depicts a graph of experimental results of an IV curve of P3HT:PCBM BHJ control devices having 2.5% power conversion efficiency. In FIG. 5, line 500 represents dark current, and line 502 represents light current.

In one of the in-situ polymerized BHJ model system used, prepared without conventional solvents, the P3HT and the PCBM (electron donor and acceptors, respectively) is dissolved in 2,5-DBT to form a homogeneous mixture spun to a thin film. Subsequently, photopolymerization may be carried out to create an SF-BHJ device. An alternative to 2,5-DBT is 2,5-diiodothiophene (2,5-DIT). However, 2,5-DIT is a solid a room temperature, and consequently, creation of a physically uniform SF-BHJ thin film is more difficult and requires elevated temperatures. The photopolymerization condition of 2,5-DBT is different from 2,5-DIT because of the different carbon-halides bond cleavage energies. FT-IR analysis may be performed to find the best condition for C—Br bond cleavage and new C—C formation to prevent any side effects such as the degradation of admixed P3HT and the formation of defect sites of the polythiophene and P3HT. Other important process factors, such as the thickness of in-situ polymerized BHJ active layer, post annealing, and the metal electrode deposition condition, may be optimized.

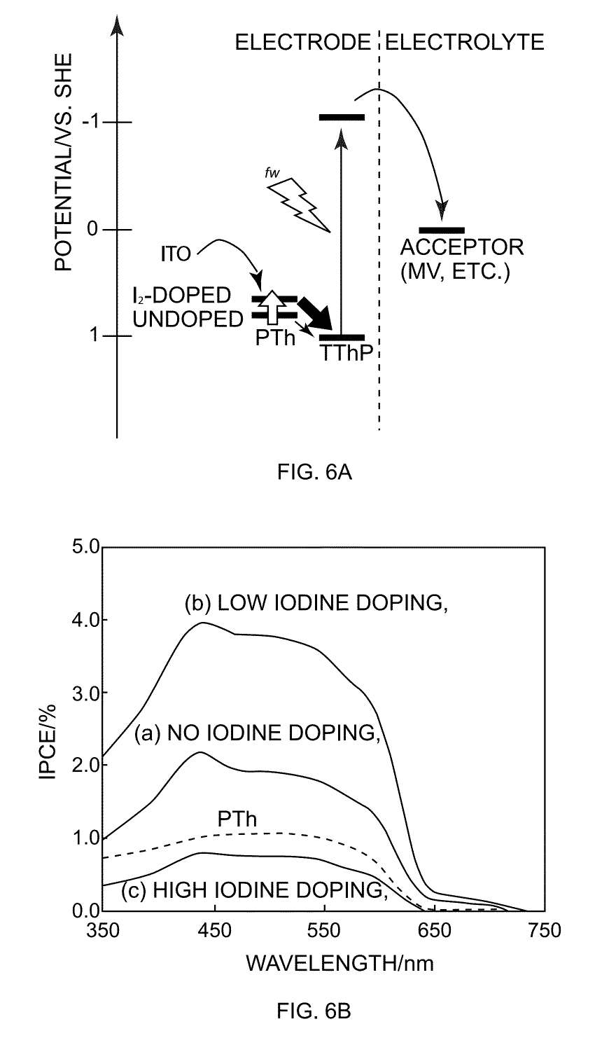

In another in-situ polymerized BHJ model system, the P3HT and the PCBM as the electron donors and acceptors, respectively, may be dissolved in 2,5-DIT to create a homogeneous mixture at slightly elevated temperatures of 40-45° C. Photopolymerization yields 2,5-DIT based in-situ polymerized BHJ devices. In this case, there could be I₂ auto-doping during the photopolymerization. Low levels of I₂-doped polythiophene may have improved power conversion efficiency due to lowered HOMO level of polythiophene. For example, FIGS. 6(a) and 6(b) are charts showing iodine doping effect on a polythiophene/porphyrin based polymer solar cell. It can be expected that a high level of I2 can degrade the power conversion efficiency because of strong metallic iodine doping of polythiophene or P3HT. For the optimization of morphology and iodine doping during photopolymerization, FT-IR analysis can be performed and TEM and X-ray analysis can be carried out also for studies of morphology and crystallization, packing density of the P3HT, and the nucleation and growth of the PCBM.

In yet another in-situ polymerized BHJ model system, 2,5-DBT- or 2,5-DBT-based solutions and polymerization of the monomer in-situ may be applied to carbon nanotube (CNT) arrays or assemblies, thus creating near ideal morphologies. Assuming the same reaction statistics as for 2,5-DIT, the average repeating unit from the photopolymerization of the 2,5-dibromothiophene is about 4-5 units and the maximum are about 10 units. Br-terminated high or low molecular weight polythiophenes can be added in various ratio to the P3HT/PCBM/2,5-DBT mixture or replace the P3HT completely, and under the homogeneous mixture phase, 2,5-DBT based photopolymerization may be carried out on this hetereogeneous mixture to create a CNT based in-situ polymerized BHJ device. Because of the added relatively high molecular weight of Br-terminated polythiophene, the phase separation rates between polythiophene and PCBM will be changed and different morphology can be expected. The morphologies may also be constraint and template by the CNT array. FT-IR, TEM, and X-ray analyses may be carried out for the study of morphology and crystallization of components. CNTs may replace the PCBM altogether and the in-situ polymerization may yield a direct method to create a semi-conducting polymer in a well controlled CNT electrode substrate.

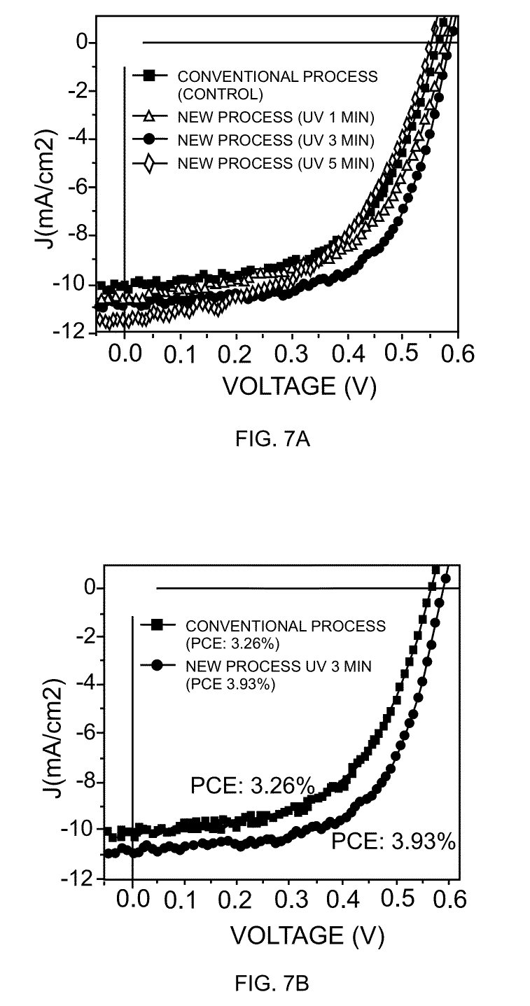

In another in-situ polymerized BHJ model process, a P3HT;PCBM blend film prepared by conventional solvent casting is exposed to the vapor 2,5-dibromothiophene and/or 2,5-diiodothiophene. Adsorbed 2,5-dibromothiophene and/or 2,5-diiodothiophene is subsequently polymerized. Power conversion efficiencies of 3.9% have been achieved in 2,5-dibromothiophene processed films, an improvement over the control system which had an efficiency of 3.2% as illustrated in FIGS. 7A and 7B.

The method of the disclosure may include mixing N (donor) and P (acceptor) types of organic semiconductors with dibromothiophene. The method also includes solvent film casting on indium tin oxide (ITO) transparent electrode (solvent evaporation). The method may also include AI top electrode formation.

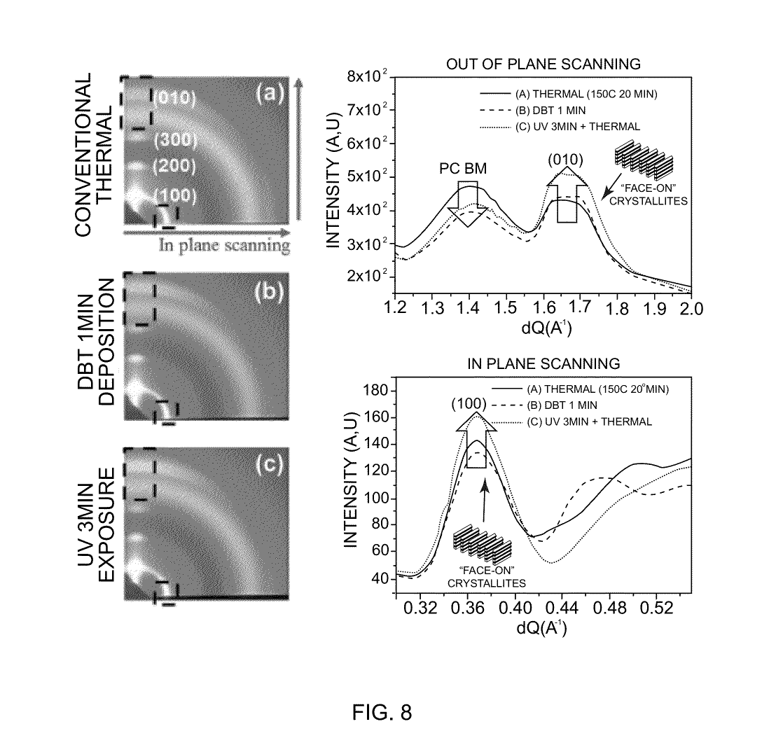

The device improvements can be related to all three major parameters that control performance: morphology, degree of crystallinity, and crystalline orientation. The enhanced degree of crystallinity can enhance the photon absorption. Improved orientation provides better charge transport, in turn resulting in improvement in device performance. An example of the improved P3HT crystalline orientation and GIWAXS data is shown in FIG. 8 for a P3HT:PCBM BHJ reference film exposed to DBT vapor, which may be a selective “solvent” for the backbone. From the integrated (100) diffraction peak intensity increase observed, one can infer that the degree of crystallization is improved. In addition, the (010) peak intensity in the out-of-plane scattering direction and the (100) intensity in the in-plane scattering direction is increasing, clearly indicating that an improvement in orientation has been achieved with a higher proportion of “face-on” orientation achieved for the new process relative to thermal annealing alone. The role of morphology has been assessed with resonant soft x-ray scattering. The results clearly indicate the creation of slightly smaller domains using the new process, and more significantly, a morphology that overall shows less scattering intensity. This indicates that the new process produces domains that are on average more intermixed and less pure. In addition, an increase in the hole transport has been observed, possibly as the result of doping with the halide that is split off from the monomer/oligomers during the photo-polymerization.

### EXAMPLES

The following non-limiting examples further explain the presently disclosed subject matter and its features:

### Example 1

FIG. 9. illustrates an exemplary process of in-situ fabrication of in-situ polymerized bulk heterojunction organic devices according to embodiments of the present disclosure. In this example, PEDOT:PSS may be cast onto ITO and subsequently annealed at elevated temperature to remove water. The solution of active materials and monomer (DBT of DIT) may be cast at room temperature on top the PEDOT:PPS/ITO substrate to variable thickness (controlled by spin speed and solution concentration). Subsequent exposure to UV light in an oxygen-free environment for variable times initiates photopolymerization and polymerization induced phase separation. Evaporation of a metal cathode completes the device.

### Example 2

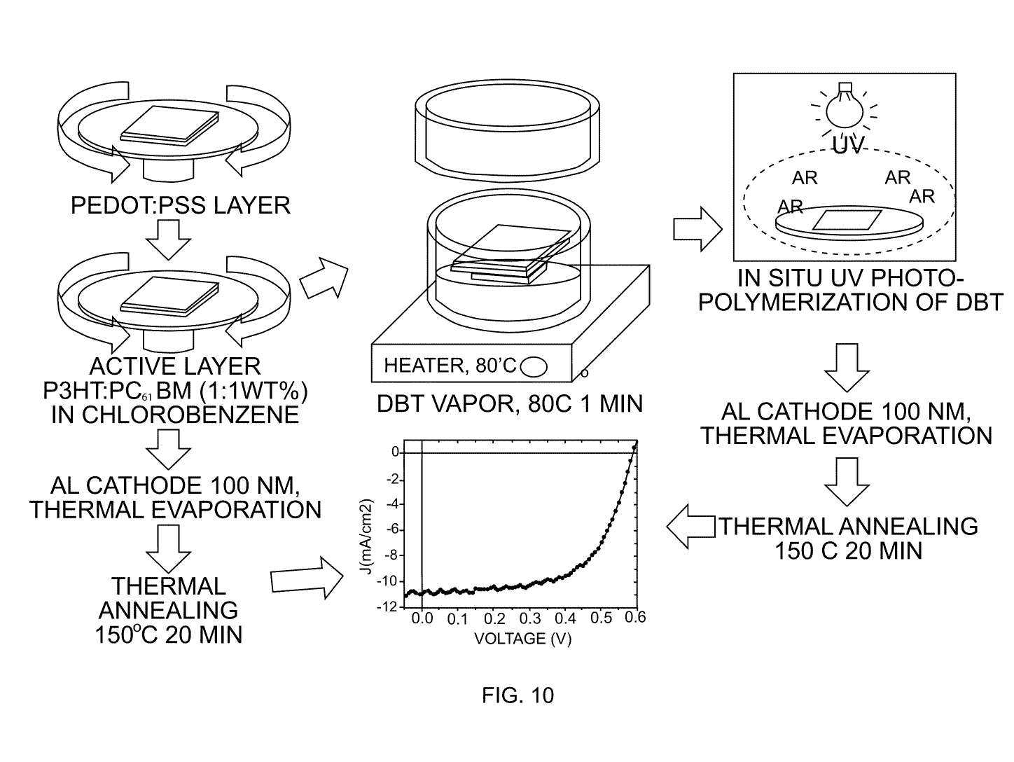

FIG. 10 illustrates an exemplary process of device fabrication according to embodiments of the present disclosure. PEDOT:PSS may be cast onto ITO to create the device anode. An active layer included of a donor-acceptor blend such as, for example, P3HT:PCBM may be cast from conventional solvents. This layer may subsequently be exposed to a monomer with selective affinity for the donor polymer backbone, such as, for example, DBT monomer and P3HT donor polymer, respectively. This may initiate some crystallization and desired crystal orientation. Subsequent UV exposure polymerizes the DBT or DIT monomer, causing polymerization initiated phase separation. A metal cathode may be evaporated to complete the device. Exemplary data for such a device has been shown in FIGS. 7A and 7B.

While the embodiments have been described in connection with the various embodiments of the various figures, it is to be understood that other similar embodiments may be used or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed:

1. A homogeneous composition for in situ polymerization to form bulk heterojunction organic devices comprising:
a monomer capable of polymerization upon short wave length photoirradiation;
at least one electron donor material; and
at least one electron acceptor material.

2. The composition of claim 1 wherein the monomer is capable of polymerizing, upon irradiation with ultraviolet light, to form a thiophene oligomer or polythiophene.

3. The composition of claim 2 wherein the monomer is a 2,5-dihalothiophene.

4. The composition of claim 3 wherein the 2,5-dihalothiophene is 2,5-dibromothiophene or short wave length photoirradiation.

5. The composition of claim 2 wherein the electron donor material is poly(3-alkyl-2,5-thiophene), wherein the alkyl group has one to twelve carbon atoms.

6. The composition of claim 2 wherein the electron acceptor material is one or more derivatives of a fullerene.

7. The composition of claim 6 wherein the derivatives of fullerene is a [6,6]phenyl-C_{61 or 71}fullerene-C₍₁₋₈₎ alkanonic acid C₍₁₋₈₎alkyl ester.

8. The composition of claim 7 wherein the derivatives of fullerene is [6,6]phenyl-C₆₁fullerene-butyric acid methyl ester.

9. The composition of claim 7 wherein the derivatives of fullerene is [6,6]phenyl-C₇₁ fullerene-butyric acid alkyl ester, wherein the alkyl group has one to six carbon atoms.

10. The composition of claim 1, wherein the electron acceptor material comprises carbon nanotubes or derivatives of carbon nanotubes.

11. A homogeneous composition for the in situ polymerization of bulk heterojunction organic devices comprising 2,5-dibromothiophene or 2,5-diiodothiophene, P3HT and PCBM.

12. A method of in-situ synthesis of a bulk heterojunction photovoltaic film, the method comprising:
casting a homogeneous composition onto a thin film on the solid substrate that is capable of acting as an anode, wherein the homogenous composition comprises a monomer capable of polymerization upon short wave length photoirradiation, at least one electron donor material, and at least one electron acceptor material; and
irradiating the thin film with ultraviolet light in an atmosphere substantially devoid of oxygen for a sufficient duration of time and at a sufficient temperature to cause photopolymerization to occur within the thin film.

13. The method of claim 12 wherein the monomer is capable of polymerizing to form a thiophene oligomer or polythiophene.

14. The method of claim 12 wherein the monomer is a 2,5-dihalothiophene.

15. The method of claim 14 wherein the 2,5-dihalothiophene is 2,5-dibromothiophene or 2,5-diiodothiophene.

16. The method of claim 12 wherein the electron donor material is poly(3-alkyl-2,5-thiophene), wherein the alkyl group has one to twelve carbon atoms.

17. The method of claim 12 wherein the electron acceptor material is one or more derivatives of a fullerene.

18. The method of claim 17 wherein the derivatives of fullerene is a [6,6]phenyl-C₆₁ fullerene-C₍₁₋₈₎ alkanonic acid C₍₁₋₈₎alkyl ester or [6,6]phenyl-C₆₁ fullerene-C₍₁₋₈₎ alkanonic acid C₍₁₋₈₎alkyl ester.

19. The method of claim 18 wherein the derivatives of fullerene is [6,6]phenyl-C₆₁ fullerene-butyric acid methyl ester or [6,6]phenyl-C₇₀ fullerene-butyric acid methyl ester.

20. The method of claim 19 wherein the derivatives of fullerene is [6,6]phenyl-C₇₁ fullerene-butyric acid alkyl ester, wherein the alkyl group has one to six carbon atoms.

21. The method of claim 12, wherein the electron acceptor material comprises carbon nanotubes or derivatives of carbon nanotubes.
